(19) United States
(12) Patent Application Publication
(10) Pub. No.: US 2009/0184319 A1
(43) Pub. Date: Jul. 23, 2009

(54) DISPLAY SUBSTRATE AND A METHOD OF MANUFACTURING THE DISPLAY SUBSTRATE

(76) Inventors: Sang-Gab Kim, Seoul (KR); Min-Seok Oh, Yongin-shi (KR); Yu-Gwang Jeong, Yongin-shi (KR); Hong-Sick Park, Suwon-si (KR); Shi-Yul Kim, Yongin-shi (KR); Jang-Soo Kim, Yongin-shi (KR); Shin-Il Choi, Seoul (KR)

Correspondence Address: Haynes and Boone, LLP;IP Section, 2323 Victory Avenue, SUITE 700, Dallas, TX, 75219, US

(21) Appl. No.: 12/328,487

(22) Filed: Dec. 4, 2008

(30) Foreign Application Priority Data
Jan. 22, 2008 (KR) 2008-6751

(51) Int. Cl. H01L 29/04; H01L 21/336

(52) U.S. Cl. 257/59; 438/160; 257/E29.003; 257/E21.414

(57) ABSTRACT

A method of manufacturing a display substrate is described. In the method, a gate line and a gate electrode are formed on a base substrate. A source metal layer is formed on the base substrate having the gate line and the gate electrode. A data line, a source electrode and a drain electrode are formed by etching the source metal layer by using an etching gas. An additive gas is provided to the base substrate having the drain electrode so that the additive gas reacts with an etching component of the etching gas to remove a by-product formed at an exposed portion of the data line, the source electrode and drain electrode. Thus, corrosion of the fine pattern due to an etching gas may be prevented and/or reduced.

### CROSS-REFERENCE TO RELATED APPLICATIONS

This application claims priority under 35 U.S.C. §119 to Korean Patent Application No. 2008-6751 filed in the Korean Intellectual Property Office on Jan. 22, 2008, the contents of which are herein incorporated by reference in their entirety.

### BACKGROUND OF THE INVENTION

1. Field of the Invention

The present invention relates to a display substrate and a method of manufacturing the display substrate. More particularly, the present invention relates to a method of manufacturing a display substrate that may be used for a liquid crystal display (LCD) apparatus and a display substrate.

2. Description of the Related Art

In general, a liquid crystal display (LCD) apparatus includes an LCD panel and a backlight assembly providing light. The LCD panel includes a display substrate including switching devices for driving pixels, an opposing substrate facing the display substrate, and a liquid crystal layer interposed between the display substrate and the opposing substrate. The LCD apparatus applies a voltage to the liquid crystal layer to control the transmittance of light provided by the backlight assembly disposed under the LCD panel to display an image.

The display substrate having switching devices, for example, thin-film transistors (TFTs), is manufactured by forming patterns through a plurality of photolithography processes. Each of the photolithography processes typically uses an individual mask. A method using four masks is being currently used to simplify the manufacturing processes and to reduce manufacturing costs. According to the four-mask method, a metal layer for a data line is first etched to form a data line, and then etched to form a source electrode, a drain electrode and a channel portion. The first and second etching processes are performed through a wet-etching method.

Aluminum (Al) or an aluminum alloy, which has relatively low resistance, is used as a material for gate lines and/or data lines in order to increase the sizes of LCD apparatuses and to improve display quality. However, aluminum has low adhesion with a pixel electrode including indium tin oxide (ITO), indium zinc oxide (IZO) and the like. Furthermore, aluminum may be diffused into an insulation layer including silicon, etc. In order to solve such problems, a molybdenum/aluminum/molybdenum triple-layer structure having molybdenum (Mo) layers respectively formed under and on an aluminum layer is used.

When a metal layer for a data line has a molybdenum/aluminum/molybdenum triple-layer structure, the metal layer for a data line is patterned through a first wet-etching process and a second wet-etching process to form a data line, a source electrode and a drain electrode in the four-mask method. However, since the wet-etching process etches an object anisotropically, a fine pattern may be difficult to form, and an active layer for a channel portion may protrude, thereby reducing an aperture ratio and causing afterimages.

### SUMMARY OF THE INVENTION

The present invention provides a method of manufacturing a display substrate capable of forming a fine pattern and capable of reducing damage to the fine pattern so as to improve the reliability of a manufacturing process.

The present invention also provides a display substrate having improved reliability.

In one aspect of the present invention, there is provided a method of manufacturing a display substrate. In the method, a gate line and a gate electrode are formed on a base substrate. A source metal layer is formed on the base substrate having the gate line and the gate electrode. A data line crossing the gate line, a source electrode connected to the data line and a drain electrode spaced apart from the source electrode are formed by etching the source metal layer using an etching gas. An additive gas is provided to the base substrate having the drain electrode so that the additive gas reacts with an etching component of the etching gas to remove a by-product formed at an exposed portion of the data line, the source electrode and drain electrode. A pixel electrode electrically connected to the drain electrode is formed.

After the by-product is removed, the base substrate having the drain electrode may be rinsed before the pixel electrode is formed. For example, the base substrate may be rinsed by using deionized water.

In another aspect of the present invention, a display substrate includes a gate line and a gate electrode connected to the gate line, a source pattern having an etched surface, on which a metal fluoride is deposited, and further includes a data line crossing the gate line, a source electrode connected to the data line and a drain electrode spaced apart from the source electrode and a pixel electrode electrically connected to the drain electrode.

According to the above, a data line is formed by wet-etching a source metal layer, and a source electrode and a drain electrode are formed by dry-etching the source metal layer to form a fine pattern.

Furthermore, a by-product formed in a process of dry-etching a source metal layer is removed by an additive gas to prevent the data line, the source electrode and the drain electrode from being corroded in following processes.

Accordingly, a fine pattern may be formed through a dry-etching process, and corrosion of the fine pattern due to an etching gas may be prevented and/or reduced. Thus, the reliability of a manufacturing process and electrical characteristics of a thin-film transistor (TFT) may be improved.

### BRIEF DESCRIPTION OF THE DRAWINGS

The above and other advantages of the present invention will become readily apparent by reference to the following detailed description when considered in conjunction with the accompanying drawings wherein:

FIG. 1 is a plan view illustrating a display substrate manufactured by a method of manufacturing a display substrate according an example embodiment of the present invention;

FIG. 2 is a cross-sectional view taken along the line I-I′ of FIG. 1;

FIG. 3 is an enlarged cross-sectional view illustrating a channel portion of FIG. 2;

FIG. 4 is a cross-sectional view illustrating processes of forming a gate pattern of the display substrate illustrated in FIG. 1;

FIGS. 5 to 9 are cross-sectional views illustrating processes of forming a source pattern and a channel portion of the display substrate illustrated in FIG. 1;

FIG. 10A is cross-sectional view illustrating processes of removing a by-product;

FIG. 10B is an enlarged cross-sectional view illustrating the channel portion of FIG. 10A;

FIG. 11 is a cross-sectional view illustrating processes of forming a passivation layer of the display substrate illustrated in FIG. 1; and

FIG. 12 is a graph illustrating electrical characteristics of a thin-film transistor (TFT) of a display substrate manufactured according to an example of the present invention.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Display Substrate

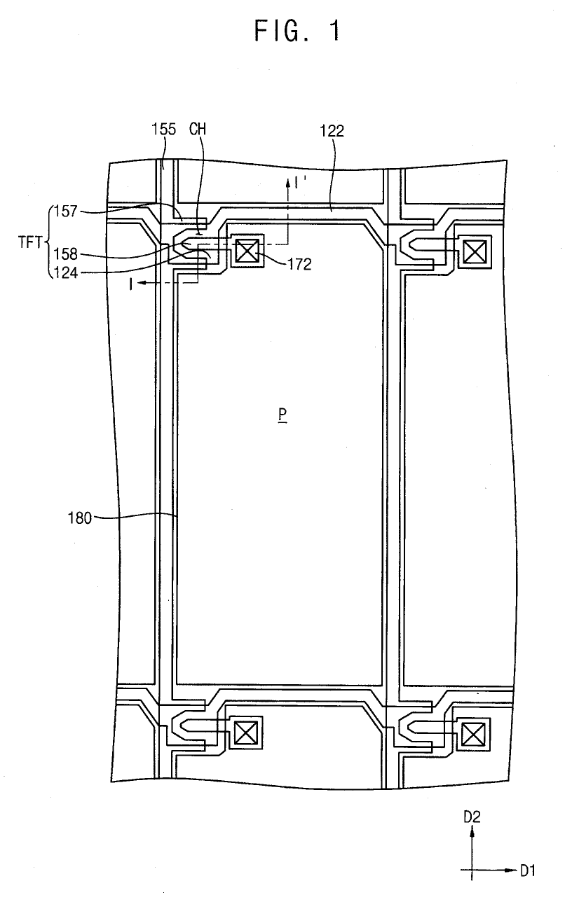

FIG. 1 is a plan view illustrating a display substrate manufactured by a method of manufacturing a display substrate according an example embodiment of the present invention.

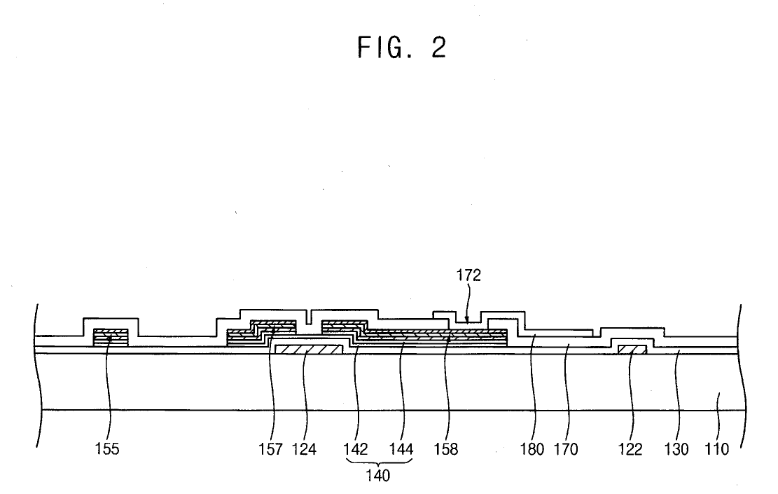

FIG. 2 is a cross-sectional view taken along the line I-I′ of FIG. 1.

Referring to FIGS. 1 and 2, a display substrate 100 includes a gate line 122, a data line 155, a thin-film transistor (TFT) as a switching device and a pixel electrode 180.

For example, the gate line 122 may extend in a first direction D1 of a base substrate 110, and a plurality of gate lines 122 may be arranged in parallel in a second direction D2 different from the first direction D1. The second direction D2 may be substantially perpendicular to the first direction D1.

The data line 155 may extend in the second direction D2, and a plurality of data lines 155 be arranged in parallel in the first direction D1. The data line 155 crosses the gate line 122.

The TFT includes a gate electrode 124, a source electrode 157 and a drain electrode 158. The gate electrode 124 is connected to the gate line 122. The source electrode 157 is connected to the data line 155. An end of the drain electrode 158 makes contact with the pixel electrode 180 through a contact hole 172 so that the TFT is electrically connected to the pixel electrode 180.

Referring to FIG. 2, the display substrate 100 further includes a gate insulation layer 180, an active layer 140 and a passivation layer 170.

The gate insulation layer 130 is formed on the base substrate 110 having the gate line 122 and the gate electrode 124.

The active layer 140 is formed on the gate insulation layer 130 overlapping with the gate electrode 124, and overlaps with the gate electrode 124. The active layer 130 is disposed between the source electrode 157 and the drain electrode 158 and between the data line 155 and the gate insulation layer 130. A channel portion CH is formed between the source electrode 157 and the drain electrode 158.

The data line 155, the source electrode 157 and the drain electrode 158 are formed by patterning a source metal layer 150 including a first sub-metal layer 151, a line metal layer 152 and a second sub-metal layer 153. A by-product may be formed at side portions of the data line 155, the source electrode 157 and the drain electrode 158.

The passivation layer 170 is formed on the base substrate 110 having the data line 155 and the source electrode 157, and the contact hole 157 is formed through the passivation layer 170 to expose a portion of the drain electrode 158.

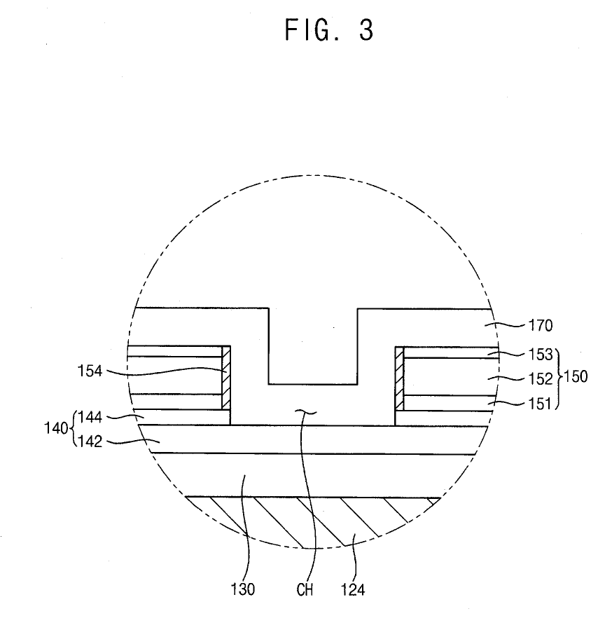

FIG. 3 is an enlarged cross-sectional view illustrating a channel portion of FIG. 2.

Referring to FIG. 3, a metal protection part 154 is formed at side portions of the source electrode 157 and the drain electrode 158, which are adjacent to the channel portion CH. The side portions of the source electrode 157 and the drain electrode 158 may be etched surfaces of the source metal layer after patterned to form the source electrode 157 and the drain electrode 158. The metal protection part 154 may be formed at a side portion of the data line 155 as well as the side portions of the source electrode 157 and the drain electrode 158.

The metal protection part 154 may include a compound formed from a reaction of a metal of the source metal layer and an added gas in the process of manufacturing the display substrate 100. Examples of the compound may include a metal fluoride such as aluminum fluoride, etc. The metal protection part 154 may prevent and/or reduce corrosion of the source electrode 157 and the drain electrode 158 in the course of the process of manufacturing the display substrate 100.

In an example embodiment, the metal protection part 154 having the compound may have a shape of a thin film covering the side portions of the source electrode 157 and the drain electrode 158. Alternatively, the compound may be randomly deposited at the side portions of the source electrode 157 and the drain electrode 158. The compound will be fully described with a description of a method of manufacturing a display substrate according to an example embodiment of the present invention.

Method of Manufacturing a Display Substrate

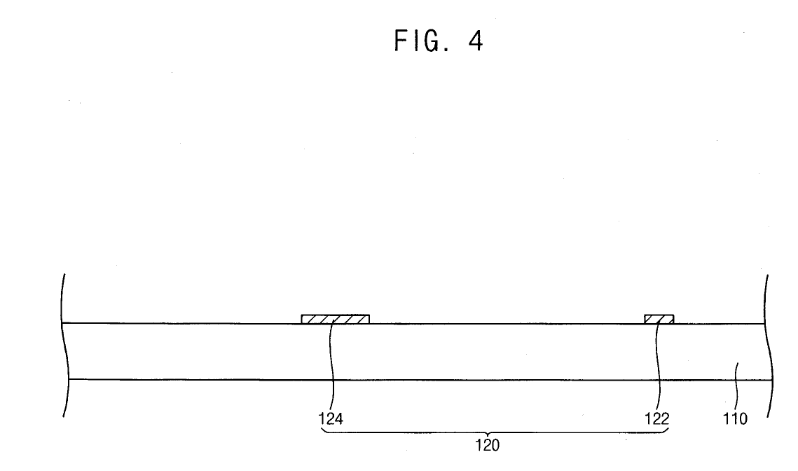

FIGS. 4, 5, 6, 7, 8, 9, 10A, 10B and 11 are cross-sectional views illustrating a method of manufacturing the display substrate illustrated in FIG. 1. Hereinafter, a method of manufacturing a display substrate according to an example embodiment of the present invention will be described with reference to FIGS. 4 to 11.

FIG. 4 is a cross-sectional view illustrating processes of forming a gate pattern of the display substrate illustrated in FIG. 1.

Referring to FIG. 4, a gate pattern 120 is formed on a base substrate 110. The gate pattern 120 includes a gate line 122 and a gate electrode 124.

For example, a gate metal layer may be formed on the base substrate 110. A first photoresist pattern may be formed on the gate metal layer by using a first mask. The gate metal layer may be etched by using the first photoresist pattern as an etching mask thereby forming the gate pattern 120. For example, the gate metal layer may be etched through a wet-etching process.

Examples of the base substrate 110 may include a transparent insulation such as a glass substrate. Examples of a material that may be used for the gate metal layer may include aluminum (Al), molybdenum (Mo), neodymium (Nd), chromium (Cr), tantalum (Ta), titanium (Ti), tungsten (W), copper (Cu), silver (Ag), an alloy thereof, etc. The gate metal layer may include a plurality of metal layers having different physical characteristics. For example, the gate metal layer may have a double-layer structure including an aluminum-containing metal layer and a molybdenum-containing metal layer.

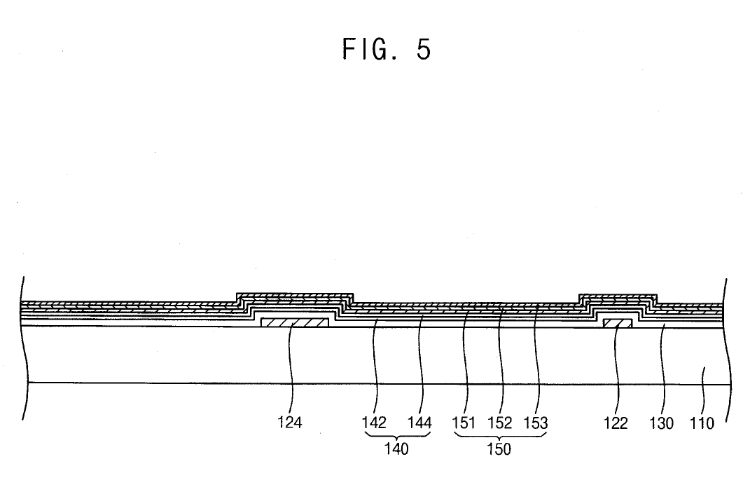

FIGS. 5 to 9 are cross-sectional views illustrating processes of forming a source pattern and a channel portion of the display substrate illustrated in FIG. 1.

Referring to FIG. 5, a gate insulation layer 130, an active layer 140 and a source metal layer 150 are sequentially formed on the base substrate 110 having the gate pattern 120. For example, the gate insulation layer 130 and the active layer 140 may be formed through a plasma-enhanced chemical vapor deposition (PECVD) method. Examples of a material that may be used for the gate insulation layer 130 may include silicon nitride (SiNx, 0<x<1), silicon oxide (SiOy, 0<y<1). The active layer 140 may include a semiconductor layer 142 and an ohmic contact layer 144. The semiconductor layer 142 is formed on the gate insulation layer 130. For example, the semiconductor layer 142 may include amorphous silicon (s-Si). The ohmic contact layer 144 is formed on the semiconductor layer 142. For example, the ohmic contact layer 144 may include n⁺ amorphous silicon (n⁺ a-Si), into which n-type impurities are implanted at a high concentration.

A source metal layer 150 is formed on the active layer 140. The source metal layer 150 includes a first sub-metal layer 151, a line metal layer 152 and a second sub-metal layer 153. For example, the source metal layer 150 may be formed through a sputtering method. The first sub-metal layer 151 may include molybdenum, and the line metal layer 152 may include aluminum, and the second sub-metal layer 153 may include molybdenum.

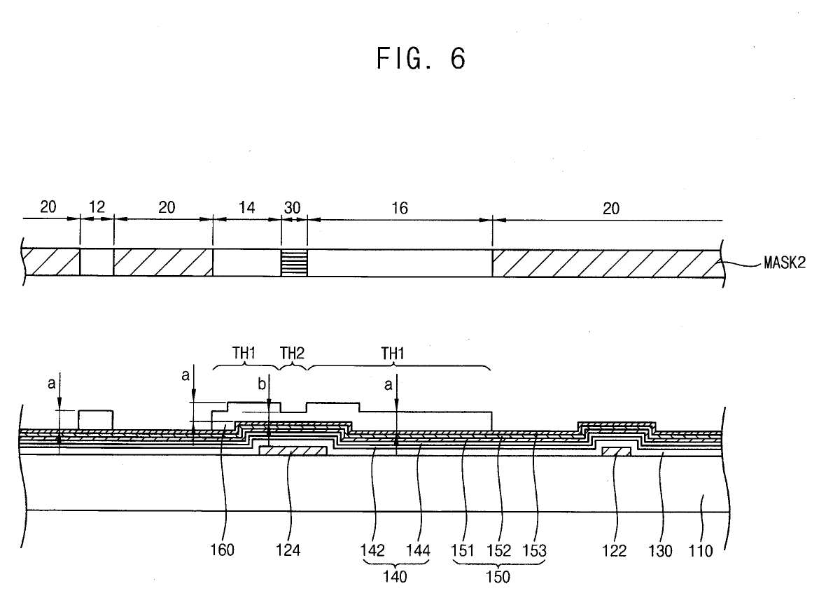

Referring to FIG. 6, a photoresist material is coated on the source metal layer 150 to form a photoresist film. The photoresist film is patterned by using a second mask (MASK2) to form a second photoresist pattern 160.

For example, the photoresist film may include a negative photoresist material so that a portion of the photoresist film, which is exposed to light, is cured and remains so that a portion of the photoresist film, which is not exposed to light, is removed. Alternatively, the photoresist film may include a positive photoresist material so that a portion of the photoresist film, which is not exposed to light, is cured and remains so that a portion of the photoresist film, which is exposed to light, is removed. The design of the second mask (MASK2) may depend on the characteristics. In the example embodiment, the photoresist film includes the negative photoresist material.

Examples of the second mask MASK2 may include a slit mask including transmitting portions 12, 14 and 16, a light-blocking portion 20 and a diffraction portion 30. The second photoresist pattern 160 includes a first thickness portion TH1 and a second thickness portion TH2.

The transmitting portions 12, 14 and 16 includes a first transmitting portion 12 corresponding to a region of the base substrate 110, in which the data line 155 illustrated in FIG. 1 is formed, a second transmitting portion 14 corresponding to a region of the base substrate 110, in which the source electrode 157 is formed, and a third transmitting portion 16 corresponding to a region of the base substrate 110, in which the drain electrode 157 is formed. The first thickness portion TH1 is disposed on the source metal layer 150 corresponding to the first to third transmitting portions 12, 14 and 16. The first thickness portion TH1 may have a first thickness ‘a’. The first thickness may be less than or substantially equal to an initial thickness of the photoresist film. The diffraction portion 30 is disposed on the base substrate 110 corresponding to the channel portion CH illustrated in FIG. 1. The second thickness portion TH2 is disposed on the source metal layer 150 corresponding to the diffraction portion 30. The second thickness portion TH2 has a second thickness ‘b’ less than the first thickness ‘a’.

Alternatively, the second mask may be a halftone mask including a semi-transmitting portion. The photoresist pattern 160 having the first thickness portion TH1 and the second thickness portion TH2 may be formed by using the halftone mask.

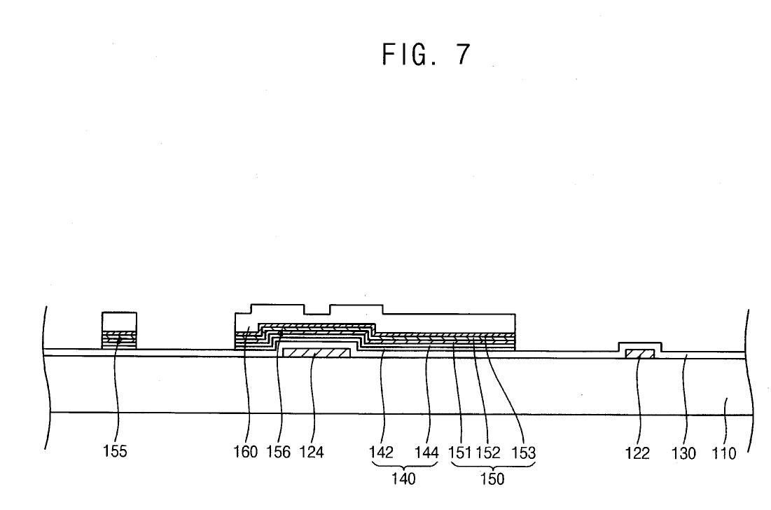

Referring to FIG. 7, the source metal layer 150 and the active layer 140 are sequentially etched by using the second photoresist pattern 160 as an etching mask.

For example, the source metal layer 150 is etched to form the data line 155 and an electrode pattern 156 connected to the data line 155. The source metal layer 150 may be etched through a wet-etching process.

The active layer 140 is etched by using the second photoresist pattern 160, the data line 155 and the electrode pattern 156 to form a channel pattern. The channel pattern remains under the data line 155 and the electrode pattern 156, and the gate insulation layer 130 is exposed in a region of the base substrate 110 excluding a region overlapping the data line 155 and the electrode pattern 156. For example, the active layer 140 may be etched through a dry-etching process.

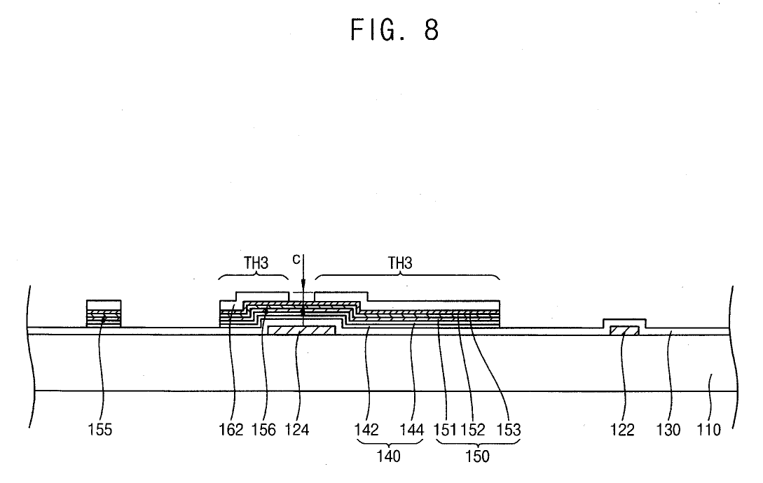

Referring to FIG. 8, the second thickness portion TH2 of the second photoresist pattern 160 is removed to form a remaining photoresist pattern 162.

The remaining photoresist pattern 162 has a third thickness portion TH3 formed from the first thickness portion TH1 reduced by the second thickness ‘b’ pf the second thickness portion TH2. The ohmic contact layer 144 of the channel pattern of the channel portion CH is exposed through the third thickness portion TH3 of the remaining photoresist pattern 162. The third thickness portion TH3 has a third thickness less than the first thickness ‘a’ of the first thickness portion TH1.

Referring to FIG. 8, an exposed portion of the electrode pattern 156 is etched by using the remaining photoresist pattern 162 as an etching mask. The electrode pattern 156 is etched to form the source electrode 157 and the drain electrode 158 of the TFT. The source electrode 157 is connected to the data line 155, and the drain electrode 158 is spaced apart from the source electrode 157.

Before etching the electrode pattern 156, an oxide layer formed from oxidized aluminum of the line metal layer 152 may be removed.

The electrode pattern 156 exposed through the remaining photoresist pattern 162 may be etched through a dry-etching process using an etching gas. Examples of the etching gas may include a chlorine-based gas containing chlorine. For example, the etching gas may include a mixture including chlorine gas (Cl₂) and boron trichloride (BCl₃).

When the source electrode 157 and the drain electrode 158 are formed, a portion of the ohmic contact layer 144 of the channel pattern is exposed through a gap region between the source electrode 157 and the drain electrode 158.

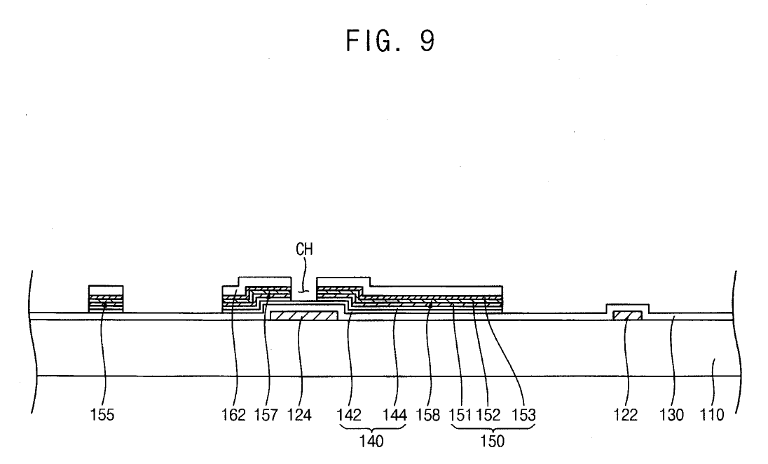

Referring to FIG. 9, an exposed portion of the ohmic contact layer 144 of the channel pattern is removed by using the remaining photoresist pattern 162, the source electrode 157 and the drain electrode 158 as an etching mask. For example, the ohmic contact layer 144 may be etched through a dry-etching process. When the ohmic contact layer 144 is etched, a portion of the remaining photoresist pattern 162 is removed so that the thickness of the remaining photoresist pattern 162 is reduced. Thus, the active layer 142 of the channel pattern is exposed to form the channel portion CH.

The processes of forming the remaining photoresist pattern 162, the source electrode 157 and the drain electrode 158 illustrated in FIGS. 7 to 9 may be sequentially performed in the same vacuum chamber.

A metal of the source metal layer 150 may react with an etching gas to form a by-product. For example, the etching gas may include a chlorine ion (Cl⁻). For example, the etching gas in the vacuum chamber may react with aluminum of the source metal layer 150 to form a by-product containing aluminum chloride.

When the by-product remains on the base substrate 110, and when the base substrate is moved out of the vacuum chamber in order to rinse the base substrate 110, the by-product may react with water vapor (H₂O) and/or hydrogen gas (H₂) while exposed to the atmosphere to generate hydrochloric acid. Thus, the base substrate 110 may be damaged by the hydrochloric acid.

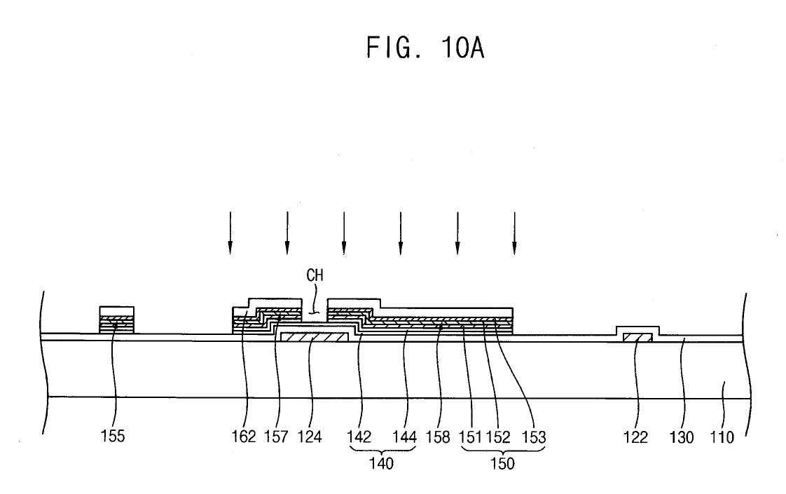

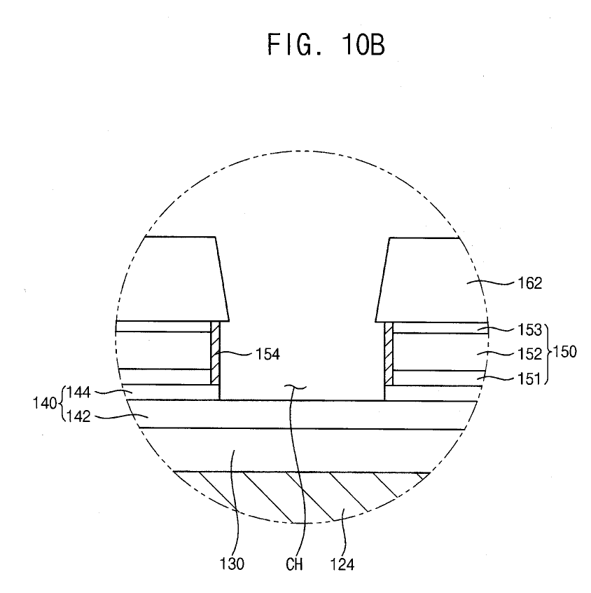

In order to improve the above-mentioned problems, the by-product on the base substrate 110 may be preferably removed before the process of rinsing the base substrate 110. A process of removing the by-product will be described with reference to FIGS. 10A and 10B.

The etching gas may further include nitrogen gas (N₂). The nitrogen gas may react with residue generated in the dry-etching process to form an organic layer at exposed side surfaces of the source electrode 157 and the drain electrode 158. The organic layer may prevent corrosion of an exposed metal after the dry-etching process.

FIG. 10A is cross-sectional view illustrating processes of removing a by-product.

Referring to FIG. 10A, an additive gas is provided to the base substrate 110 having the channel portion CH in the vacuum chamber, in which the processes illustrated in FIGS. 6 and 7 are performed. The additive gas may contain fluorine (F). For example, the additive gas may include trifluoromethane (CHF₃), tetrafluoromethane (CF₄), sulfur hexafluoride (SF₆) and the like. The additive gas may further include oxygen gas (O₂) and/or water vapor (H₂O). The oxygen gas and/or water vapor may promote generation of an additive component of the additive gas. The additive component may be formed from the additive gas discomposed by plasma. Examples of the additive component may include a fluorine radical (F⁻).

The additive gas is provided to the base substrate 110 having the channel portion CH so that the by-product is removed. When the additive gas is provided, the additive component having high reactivity may break a bond between a metal and an etching component of the by-product. Thus, the additive component is substituted for the etching component of the by-product, and is combined with the metal to generate a compound including the additive component combined with the metal. The reactivity of the additive component with respect to the metal is greater than the reactivity of the etching component with respect to the metal. Thus, the bond between the metal and the etching component may be easily broken by the additive component. The compound may include a metal fluoride, and examples of the metal fluoride may include aluminum fluoride. Thus, forming the metal fluoride and removing the by-product may remove chlorine ions of the etching component.

The additive component may react with aluminum of the line metal layer 152 to generate aluminum fluoride. An internal pressure of the vacuum chamber in the process of providing the additive gas may be about 15 milliTorr (mTorr) to about 200 mTorr so that an excessive amount of the aluminum fluoride may be not generated.

The base substrate 110 having the channel portion CH is exposed to the atmosphere in the course of moving the base substrate 110 having the channel portion from the vacuum chamber to a rinsing chamber for removing an etching component such as chlorine ions. Since the by-product is removed from the base substrate 110 having the channel portion CH before the base substrate 110 is moved out from the vacuum chamber, hydrochloric acid is not generated due to water vapor (H₂O) and/or hydrogen gas (H₂) in the atmosphere.

Even if chlorine ions remain on the base substrate 110 having the channel portion when the base substrate 110 is exposed to the atmosphere, the data line 155, the source electrode 157 and the drain electrode 158 are protected by aluminum fluoride formed at side surfaces of the data line 155, the source electrode 157 and the drain electrode 158.

FIG. 10B is an enlarged cross-sectional view illustrating the channel portion of FIG. 10A. Referring to FIG. 10B, the aluminum fluoride is deposited along an exposed surface of the line metal layer 152. The aluminum fluoride forms a metal protection part 154 covering an exposed portion of the line metal layer 152. The metal protection part 154 may have a shape of a layer formed along the exposed surface of the line metal layer 152. Alternatively, the metal protection part 154 may have a random shape.

When the aluminum fluoride is deposited along the exposed surface of the line metal layer 152, a protruding portion of the ohmic contact layer 144, which protrudes from side portions of the source electrode 157 and/or the drain electrode 158, is reduced thereby increasing an aperture ratio. For example, the length of the protruding portion of the ohmic contact layer 144 is about 1.5 μm without the metal protection part 154. However, the length of the protruding portion of the ohmic contact layer 144 is about 0.5 μm when the aluminum fluoride is deposited along the exposed surface of the line metal layer 152.

In a process of rinsing the base substrate 110, deionized water is provided to the base substrate 110 to dissolve chlorine ions. Thus, remaining chlorine ions are removed from the base substrate 110. For example, the base substrate 110 may be rinsed through a dipping method including dipping the base substrate 110 into a rinsing container including deionized water. Alternatively, the base substrate 110 may be rinsed through a spray method including spraying deionized water at high pressure to the base substrate 110. The base substrate 110 may be rinsed through both the dipping method and the spray method. A portion of the metal protection part 154 may be removed from the base substrate 110 in the rinsing process.

The temperature of the deionized water may be about 50° C. to about 80° C. in order to increase a ratio of dissolving chlorine ions in the deionized water.

Thereafter, the remaining photoresist pattern 162 is removed from the base substrate 110. For example, the base substrate 110 may be inserted into a strip container receiving a stripping solution to dissolve the remaining photoresist pattern 162 in the stripping solution so that the remaining photoresist pattern 162 may be removed from the base substrate 110. Alternatively, the remaining photoresist pattern 162 may be removed from the base substrate 110 through an ashing process.

When the remaining photoresist pattern 162 is removed after the etching component is removed, an amount of impurities formed from reaction of the etching component and a rinsing component used in the process removing the remaining photoresist pattern 162 may be reduced.

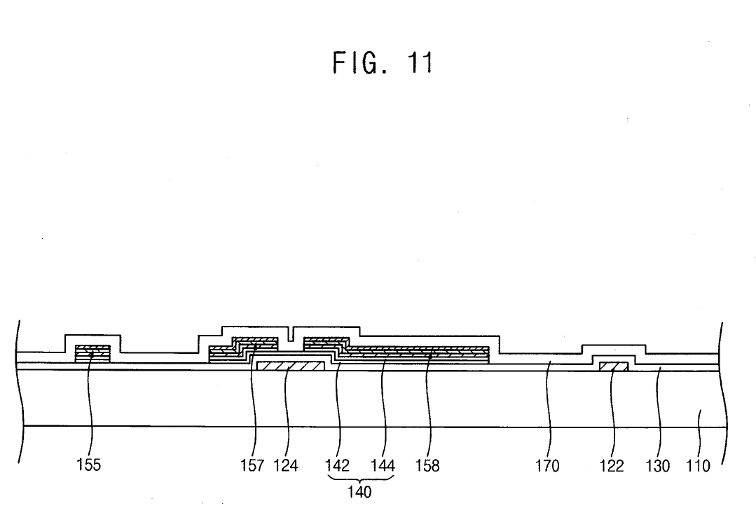

FIG. 11 is a cross-sectional view illustrating processes of forming a passivation layer of the display substrate illustrated in FIG. 1.

Referring to FIG. 11, the passivation layer 170 is formed to cover the data line 155, the source electrode 157 and the drain electrode 158 of the base substrate 110. Examples of a material that may be used for the passivation layer 170 may include silicon nitride, silicon oxide and the like.

Referring to FIGS. 1 and 11, a portion of the passivation layer 170 on the drain electrode 158 is removed to form a contact hole 172 exposing the drain electrode 158. A transparent electrode layer is formed on the base substrate 110 having the passivation layer 170, through which the contact hole 172 is formed. The transparent electrode layer is patterned to form a pixel electrode 180. The pixel electrode 180 makes contact with the drain electrode 158 through the contact hole 172 so that the TFT is electrically connected to the pixel electrode 180. The pixel electrode 180 may include a transparent conductive material. Examples of a material that may be used for the pixel electrode 180 may include indium zinc oxide (IZO), indium tin oxide (ITO) and the like.

Evaluation of Electrical Characteristics of TFT

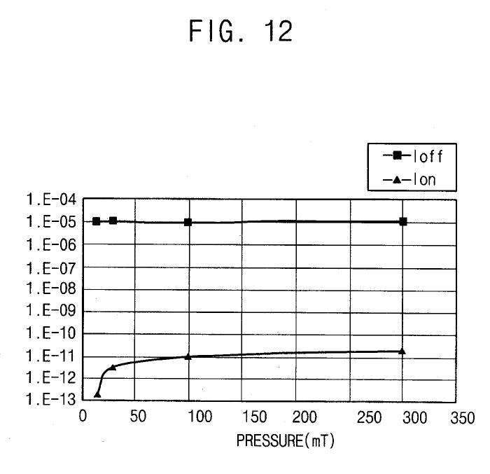

FIG. 12 is a graph illustrating electrical characteristics of a TFT of a display substrate manufactured according to an example of the present invention.

An additive gas was provided into a vacuum chamber under a range of about 15 mTorr to about 300 mTorr to manufacture a plurality of TFTs. In order to evaluate the electrical characteristics of the TFT, an off-current I_{off} and an on-current Iₒₙ of the TFTs were measured.

Referring to FIG. 12, the on-current of the TFT formed under a pressure of about 15 mTorr was about 9.60×10⁻⁶ A, and the on-current of the TFT formed under a pressure of about 30 mTorr was about 9.73×10⁻⁶ A, and the on-current of the TFT formed under a pressure of about 100 mTorr was about 9.24×10⁻⁶ A, and the on-current of the TFT formed under a pressure of about 200 mTorr was about 9.47×10⁻⁶ A, and the on-current of the TFT formed under a pressure of about 300 mTorr was about 9.9×10⁻⁶ A. Thus, it can be noted that the on-currents of the TFTs were substantially similar to each other.

However, the off-current of the TFT formed under a pressure of about 15 mTorr was about 1.90×10⁻¹³ A, and the off-current of the TFT formed under a pressure of about 30 mTorr was about 3.39×10⁻¹² A, and the off-current of the TFT formed under a pressure of about 100 mTorr was about 1.01×10⁻¹¹ A, and the off-current of the TFT formed under a pressure of about 200 mTorr was about 1.35×10⁻¹¹ A, and the off-current of the TFT formed under a pressure of about 300 mTorr was about 2.07×10⁻¹¹ A.

When an internal pressure of the vacuum chamber is more than about 200 mTorr, an amount of the fluorine radical is excessively increased in the vacuum chamber. The fluorine radical reacts with an organic material in the vacuum chamber to generate impurities and to generate an excessive amount of aluminum fluoride. The impurities and the excessive aluminum fluoride may increase an off-current of a TFT thereby deteriorating electrical characteristics of the TFT. Thus, the internal pressure of the vacuum chamber may be preferably equal to or less than about 200 mTorr.

When the internal pressure of the vacuum chamber is less than about 15 mTorr, fluorine radical is hardly generated. Furthermore, when the internal pressure of the vacuum chamber is less than about 15 mTorr, the operation of a device for a dry-etching may be unstable. Thus, the internal pressure of the vacuum chamber may be preferably equal to or more than about 15 mTorr.

According to the above, a data line is formed by wet-etching a source metal layer, and a source electrode and a drain electrode are formed by dry-etching the source metal layer to form a fine pattern. An etching component of an etching gas may be prevented from reacting with a metal of the source electrode and the drain electrode to corrode the source electrode and the drain electrode after dry-etching the source metal layer.

Accordingly, a fine pattern may be formed through a dry-etching process, and corrosion of the fine pattern due to an etching gas may be prevented and/or reduced. Thus, the reliability of a manufacturing process and electrical characteristics of a TFT may be improved.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A method of manufacturing a display substrate, the method comprising:
forming a gate line and a gate electrode on a base substrate;
forming a source metal layer on the base substrate having the gate line and the gate electrode;
forming a data line crossing the gate line, a source electrode connected to the data line and a drain electrode spaced apart from the source electrode by etching the source metal layer by using an etching gas;
providing an additive gas to the base substrate having the drain electrode so that the additive gas reacts with an etching component of the etching gas to remove a by-product formed at an exposed portion of the data line, the source electrode and drain electrode; and
forming a pixel electrode electrically connected to the drain electrode.

2. The method of claim 1, wherein the by-product is removed by substituting an additive component of the additive gas for the etching component combined with the source metal layer.

3. The method of claim 2, wherein the reactivity of the additive component with respect to the source metal layer is greater than the reactivity of the etching component with respect to the source metal layer.

4. The method of claim 3, wherein the etching gas contains chlorine, and the etching component comprises a chlorine ion.

5. The method of claim 3, wherein the additive gas contains fluorine, and the additive component comprises a fluorine radical.

6. The method of claim 5, wherein the additive gas comprises at least one selected from the group consisting of trifluoromethane (CHF₃), tetrafluoromethane (CF₄) and sulfur hexafluoride (SF₆).

7. The method of claim 5, wherein the additive gas further comprises oxygen gas and/or water vapor.

8. The method of claim 1, wherein the by-product is removed under a pressure of about 15 milliTorr (mTorr) to about 200 mTorr.

9. The method of claim 1, wherein forming the data line, the source electrode and the drain electrode comprises:
forming an active layer between the source metal layer and the base substrate having the gate line and the gate electrode before forming the source metal layer;
forming a photoresist pattern on the source metal layer;
etching the source metal layer by using the photoresist pattern as an etching mask to form the data line and an electrode pattern connected to the data line;
forming a remaining photoresist pattern by using the photoresist pattern, the remaining photoresist pattern exposing the electrode pattern in a region between the source electrode and the drain electrode;
dry-etching an exposed portion of the electrode pattern by using the remaining photoresist pattern as an etching mask to form the source electrode and the drain electrode; and
etching the active layer by using the remaining photoresist pattern, the source electrode and the drain electrode as an etching mask to form a channel portion.

10. The method of claim 9, wherein the by-product is removed after the channel portion is formed.

11. The method of claim 9, further comprising rinsing the base substrate having the drain electrode for removing the etching component after the by-product is removed.

12. The method of claim 11, wherein the base substrate is rinsed while exposed to the atmosphere by using deionized water.

13. The method of claim 12, wherein the deionized water is sprayed into the base substrate having the drain electrode.

14. The method of claim 11, further comprising removing the remaining photoresist pattern after rinsing the base substrate.

15. The method of claim 1, wherein the source metal layer comprises a first metal layer containing aluminum.

16. The method of claim 15, wherein the source metal layer further comprises a second metal layer formed on the first metal layer and a third metal layer formed under the first metal layer.

17. The method of claim 16, wherein the second and third metal layers contain molybdenum.

18. A display substrate comprising:
a gate line and a gate electrode connected to the gate line;
a source pattern having an etched surface, on which a metal fluoride is deposited, and including a data line crossing the gate line, a source electrode connected to the data line and a drain electrode spaced apart from the source electrode; and
a pixel electrode electrically connected to the drain electrode.
